(19) United States
(12) Patent Application Publication
(10) Pub. No.: US 2009/0189285 A1
(43) Pub. Date: Jul. 30, 2009

(54) ON CHIP THERMOCOUPLE AND/OR POWER SUPPLY AND A DESIGN STRUCTURE FOR SAME

(76) Inventor: John Zuidema Colt, JR., Williston, VT (US)

Correspondence Address: SCHMEISER, OLSEN & WATTS, 22 CENTURY HILL DRIVE, SUITE 302, LATHAM, NY, 12110, US

(21) Appl. No.: 12/018,827

(22) Filed: Jan. 24, 2008

(51) Int. Cl. H01L 23/52

(52) U.S. Cl. 257/756; 257/758; 257/E23.141

(57) ABSTRACT

A thermocouple and power supply structure. The structure is interleaved through a substrate. The structure includes a first through via extending through the substrate and connected to a first contact on a top surface and a second contact on a bottom surface of the substrate, through via extending through the substrate and connected to the second contact and a third contact on the top surface of the substrate. The first contact, first through via and third contact formed from a first material and the second contact and second through via formed from a second material that is different from the first material.

### FIELD OF THE INVENTION

The present invention relates to the field of integrated circuits; more specifically, it relates to an integrated chip having an on chip thermocouple and/or power supply and a design structure for same.

### BACKGROUND OF THE INVENTION

Many integrated circuits utilize batteries or solar cells as power sources. However batteries need to be replaced or recharged and solar cells are only functional when exposed to light. Further, solar cells and batteries are separate off-chip units, which greatly increase the size of any electronic device incorporating a power source and an integrated circuit chip. Accordingly, there exists a need in the art to overcome the deficiencies and limitations described hereinabove. Another difficulty is the measurement of the temperature of an active integrated circuit chip. Existing on-chip temperature sensors require extensive calibration procedures and a located so as to only measure temperature at the measuring point as opposed to measuring heat flow through the substrate.

### SUMMARY OF THE INVENTION

A first aspect of the present invention is a structure, comprising: a semiconductor substrate having opposite top and bottom surfaces; an electrically conductive first through via extending through the substrate from the top surface to the bottom surface, the first through via electrically isolated from the substrate by a first dielectric layer; an electrically conductive second through via extending through the substrate from the top surface to the bottom surface, the second through via electrically isolated from the substrate by a second dielectric layer; a first region of the substrate intervening between the first and second through vias; an electrically conductive first contact formed on a top surface of the first through via, proximate to the top surface of the substrate, the first contact electrically isolated from the substrate by a third dielectric layer; an electrically conductive second contact formed on a bottom surface of the first through via and a bottom surface of the second through via, proximate to the bottom surface of the substrate, the second contact electrically isolated from the substrate by a fourth dielectric layer; an electrically conductive third contact formed on a top surface of the second through via, proximate to the top surface of the substrate, the third contact electrically isolated from the substrate by a fifth dielectric layer; and the first contact, the first through via and the third contact formed from a first material and the second contact and the second through via formed from a second material, the second material different from the first material.

A second aspect of the present invention is a design structure for the structure of claim 1.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is cross section through an integrated circuit having a thermocouple or power source according to an embodiment of the present invention;

FIG. 2 is a cross section through an integrated circuit having a multi-cell power source according to an embodiment of the present invention; and

FIG. 3 is a block diagram of an exemplary design flow used in semiconductor design, manufacturing, and/or test.

### DETAILED DESCRIPTION OF THE INVENTION

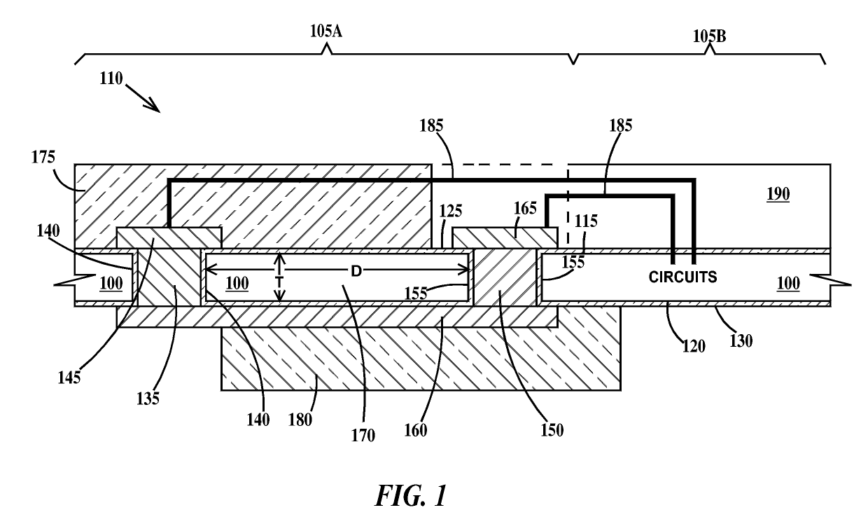

FIG. 1 is cross section through an integrated circuit having a thermocouple or power source according to an embodiment of the present invention. In FIG. 1, a semiconductor substrate 100 includes a thermocouple/power supply region 105A and a circuit region 105B. In one example semiconductor substrate 100 comprises silicon. A device 110 is formed in region 105A and integrated circuits comprising one or more devices selected from the group consisting of field effect transistors (FETs), bipolar transistors, diodes, resistors, capacitors and inductors are formed in circuit region 105B. Substrate 100 includes a top surface 115 and a bottom surface 120. A dielectric layer 125 is formed on top surface 115 and a dielectric layer 130 is formed on bottom surface 120.

Device 110 includes an electrically conductive first through via 135 extending through substrate 100 from top surface 115 to bottom surface 120. A sidewall dielectric layer 140 electrically isolates first through via 135 from substrate 100. An electrically conductive first contact 145 is formed over top surface 115 and electrically contacts first through via 135. Dielectric layer 125 electrically isolates first contact 145 from substrate 100. Device 110 includes an electrically conductive second through via 150 extending through substrate 100 from top surface 115 to bottom surface 120. A sidewall dielectric layer 155 electrically isolates second through via 150 from substrate 100. An electrically conductive second contact 165 is formed over top surface 115 and electrically contacts second through via 155. Dielectric layer 125 electrically isolates second contact 150 from substrate 100. Device 110 includes an electrically conductive third contact 160 formed over bottom surface 120. Third contact 160 electrically coinnects first through via 135 to second through via 150. Dielectric layer 130 electrically isolates third contact 160 from substrate 100.

First through via 135 and second through via 150 are separated a distance D by a region 170 of substrate 100. Substrate 100 has a thickness T. In one example, D is equal to or greater than 10 times T. Device 110 includes an optional upper thermally insulating layer 175 extending over region 170 and over first through via 135 but not over second through via 150 and an optional lower thermally insulating layer 180 extending under region 170 and under second through via 150 but not under first through via 135.

First through via 135 and first and second contacts 145 and 165 are formed of a first material and second through via 150 and third contact 180 are formed of a second material different from the first material. In one example, the first and second materials are dependently selected from the group consisting of tungsten, aluminum, copper, titanium tantalum, titanium nitride, tantalum nitride, a first polysilicon and a second polysilicon, the first polysilicon and the second polysilicon having different dopant types, different doping levels or both different doping types and different dopant concentrations. Thermocouple junctions are formed at the interface between first through via 135 and third contact 160 and at the interface between second through via 150 and second contact 165.

Wires 185 electrically connect first and second contacts 135 and 150 to circuits in circuit region 100. A wiring region 190 over top surface 120 contains one or more interlevel dielectric wiring each containing electrically conductive wires interconnected to devices in substrate 100 and to each other as is known in the art. Wires 185 are illustrated schematically and do not represent the physical locations of the wires.

In operation, top surface 125 must be at a different temperature than bottom surface 120 of substrate 120 in region 105A in order to generate a voltage between first contact 135 and second contact 145 that is a function of the temperature difference between the top and bottom of the substrate. In one example, the junction of 135/165 is the reference junction and the junction of 150/160 is the measurement junction. In one example, the junction between 150/165 is the hot junction and the junction between 135/160 is the cold junction. In one example, wiring region 190 does not extend over second contact 165. When used to generate electrical power from an external heat source and heat sink, it is advantageous that wiring region 190 be located so as to maximize the temperature difference between junction 150/165 and junction 135/160. When used as an on-chip temperature measuring device, it is advantageous that wiring region 190 extend over second contact 165 in order to bring the thermocouple junction 150/165 to a temperature as close as possible to the temperature of the circuit region (labeled circuits) in substrate 100.

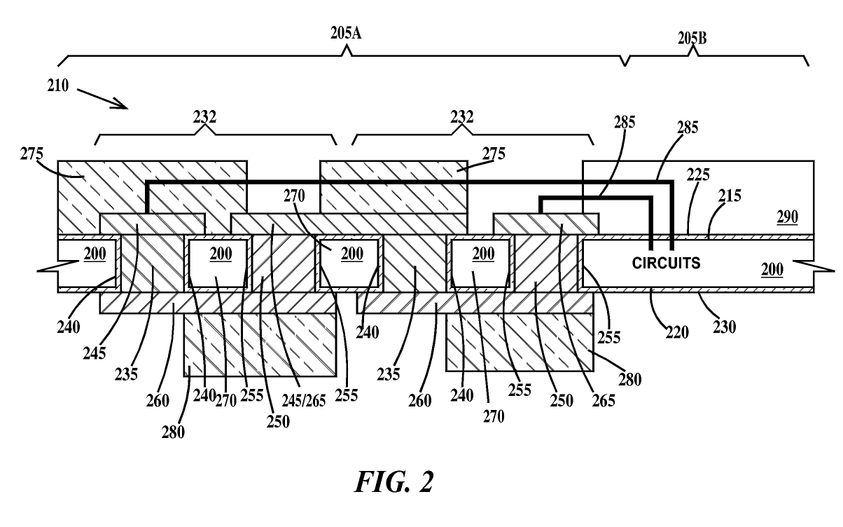

FIG. 2 is a cross section through an integrated circuit having a multi-cell power source according to an embodiment of the present invention. In FIG. 2, a semiconductor substrate 200 includes a power region 205A and a circuit region 205B. In one example semiconductor substrate comprises silicon. A power source 210 is formed in power region 205A and integrated circuits comprising one or more devices selected from the group consisting of field effect transistors (FETs), bipolar transistors, diodes, resistors, capacitors and inductors are formed in circuit region 205B. Substrate 200 includes a top surface 225 and a bottom surface 220. A dielectric layer 225 is formed on top surface 225 and a dielectric layer 230 is formed on bottom surface 220.

Power source 210 includes multiple interconnected power cells 232 (only two are illustrated in FIG. 2 by way of example, there may be more). Each power cell 232 includes an electrically conductive first through via 235 extending through substrate 200 from top surface 225 to bottom surface 220. A sidewall dielectric layer 240 electrically isolates first through via 235 from substrate 200. An electrically conductive first contact 245 is formed over top surface 225 and electrically contacts first through via 235. Dielectric layer 225 electrically isolates first contact 245 from substrate 200. Each power cell 232 includes an electrically conductive second through via 250 extending through substrate 200 from top surface 225 to bottom surface 220. A sidewall dielectric layer 255 electrically isolates second through via 250 from substrate 200. An electrically conductive second contact 265 is formed over top surface 225 and electrically contacts second through via 255. Dielectric layer 225 electrically isolates second contact 250 from substrate 200. Each power cell 232 includes an electrically conductive third contact 260 formed over bottom surface 220. Third contact 260 electrically connects first through via 235 to second through via 250. Dielectric layer 230 electrically isolates third contact 260 from substrate 200.

Each pair of first through vias 235 and second through vias 250 are separated by a region 270 of substrate 200. First and second contacts 235 and 245 of adjacent power cells 232 are integrally formed and are labeled 235/245 in FIG. 2.

First through via 235 and first and second contacts 245 and 265 are formed of a first material and second through via 250 and third contact 260 are formed of a second material different from the first material. In one example, the first and second materials are dependently selected from the group consisting of tungsten, aluminum, copper, titanium tantalum, titanium nitride, tantalum nitride, a first polysilicon and a second polysilicon, the first polysilicon and the second polysilicon having different dopant types, different doping levels or both different doping types and different dopant concentrations. Thermocouple junctions are formed at the interface between first through via 235 and third contact 260 and at the interface between second through via 250 and second contact 265. Power source 210 includes an optional upper thermally insulating layer 275 extending over the top surface of substrate 200 in region 205A except over junctions 245/250 and 265/250 and an optional lower thermally insulating layer 280 extending under the bottom surface of substrate 200 in region 205A except for junctions 235/260.

Wires 285 electrically connect first and second contacts 235 and 250 to circuits in circuit region 200. A wiring region 290 over top surface 220 contains one or more interlevel dielectric wiring each containing electrically conductive wires interconnected to devices in substrate 200 and to each other as is known in the art. Wires 285 are illustrated schematically and do not represent the physical locations of the wires.

While two power cells 232 wired in series are illustrated in FIG. 2, as few as one power cell 232 may be used or more than two. When multiple power cells 232 are used, they may be wired in series, in parallel or in combinations of series and parallel to increase respectively voltage, current or both voltage and current.

In operation as a power source, top surface 225 must be at a different temperature than bottom surface 220 of substrate 220 in region 205A in order to generate power. For power generation, it is advantageous that wiring region 290 does not extend over power region 205A.

Device 110 of FIG. 1 and power source 210 of FIG. 2 may be formed in a same integrated circuit chip along with other integrated circuits as are known in the art.

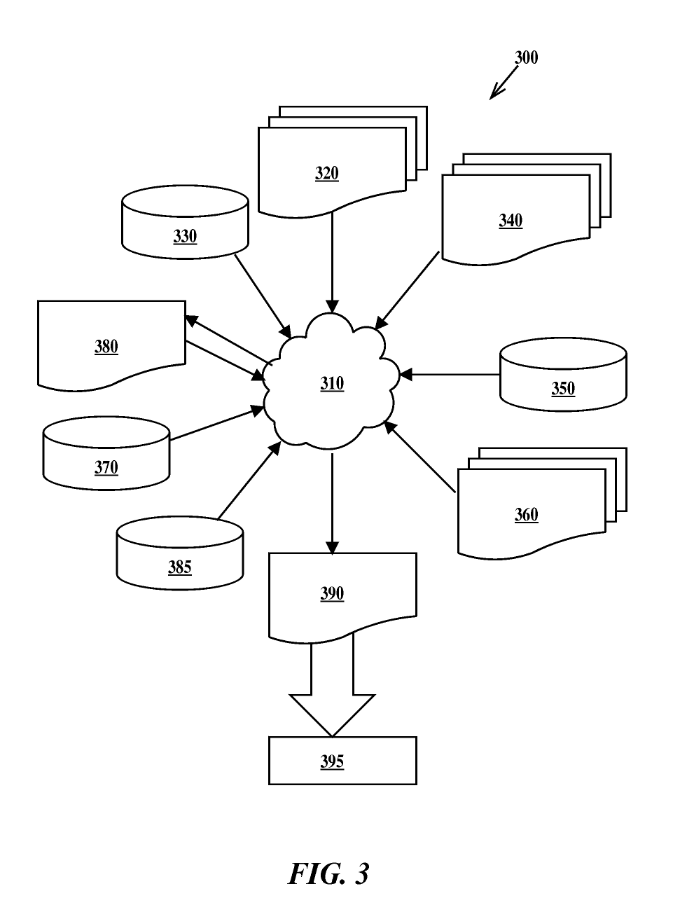

FIG. 3 is a block diagram of an exemplary design flow 300 used in semiconductor design, manufacturing, and/or test. Design flow 300 may vary depending on the type of IC being designed. For example, a design flow 300 for building an application specific IC (ASIC) may differ from a design flow 300 for designing a standard component. A design structure 320 is preferably an input to a design process 310 and may come from an IP provider, a core developer, or other design company or may be generated by the operator of the design flow, or from other sources. Design structure 320 comprises an embodiment of the invention as shown in FIGS. 1 and 2 in the form of schematics or HDL, a hardware-description language (e.g., Verilog, VHDL, C, etc.). Design structure 320 may be contained on one or more machine readable medium. For example, design structure 320 may be a text file or a graphical representation of an embodiment of the invention as shown in FIG. 1 and 2. Design process 310 preferably synthesizes (or translates) an embodiment of the invention as shown in FIGS. 1 and 2 into a netlist 380, where netlist 380 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 380 is re-synthesized one or more times depending on design specifications and parameters for the circuit.

Design process 310 may include using a variety of inputs; for example, inputs from library elements 330 which may house a set of commonly used elements, circuits, and devices, including models, layouts, and symbolic representations, for a given manufacturing technology (e.g., different technology nodes, 32 nm, 45 nm, 30 nm, etc.), design specifications 340, characterization data 350, verification data 360, design rules 370, and test data files 385 (which may include test patterns and other testing information). Design process 310 may further include, for example, standard circuit design processes such as timing analysis, verification, design rule checking, place and route operations, etc. One of ordinary skill in the art of integrated circuit design can appreciate the extent of possible electronic design automation tools and applications used in design process 310 without deviating from the scope and spirit of the invention. The design structure of the invention is not limited to any specific design flow.

Design process 310 preferably translates an embodiment of the invention as shown in FIGS. 1 and 2, along with any additional integrated circuit design or data (if applicable), into a second design structure 330. Design structure 330 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 330 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 1 and 2. Design structure 330 may then proceed to a stage 335 where, for example, design structure 330: proceeds to tape-out, is released to manufacturing, is released to a mask house, is sent to another design house, is sent back to the customer, etc.

Thus the present invention provides an integrated circuit chip having a thermocouple, a power supply or both a thermocouple and a power supply.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

1. A structure, comprising:
a semiconductor substrate having opposite top and bottom surfaces;
an electrically conductive first through via extending through said substrate from said top surface to said bottom surface, said first through via electrically isolated from said substrate by a first dielectric layer;
an electrically conductive second through via extending through said substrate from said top surface to said bottom surface, said second through via electrically isolated from said substrate by a second dielectric layer;
a first region of said substrate intervening between said first and second through vias;
an electrically conductive first contact formed on a top surface of said first through via, proximate to said top surface of said substrate, said first contact electrically isolated from said substrate by a third dielectric layer;
an electrically conductive second contact formed on a bottom surface of said first through via and on a bottom surface of said second through via proximate to said bottom surface of said substrate, said second contact electrically connecting said first and second through vias, said second contact electrically isolated from said substrate by a fourth dielectric layer;
an electrically conductive third contact formed on a top surface of said second through via proximate to said top surface of said substrate, said third contact electrically isolated from said substrate by a fifth dielectric layer; and
said first contact, said first through via and said third contact formed from a first material and said second contact and said second through via formed from a second material, said second material different from said first material.

2. The structure of claim 1, further including:
a first thermally insulating layer proximate to said top surface of said substrate over said first contact and said first region of said substrate, but not over said third contact; and
a second thermally insulating layer proximate to said bottom surface of said substrate over said second contact and said first region of said substrate, but not over a region of said second contact that is over said first through via.

3. The structure of claim 1, wherein said first and second materials are dependently selected from the group consisting of tungsten, aluminum, copper, titanium tantalum, titanium nitride, tantalum nitride, a first polysilicon and a second polysilicon, the first polysilicon and the second polysilicon having different dopant types, different doping levels or both different doping types and different dopant concentrations.

4. The structure of claim 1, further including integrated circuits formed in a second region of said substrate and electrically connected to said first and third contacts.

5. The structure of claim 1, where in a width of said first region measured between said first and second through vias is equal to greater than ten times a thickness of said substrate between said top and bottom surfaces of said substrate.

6. The structure of claim 1, wherein said substrate comprises silicon.

7. (canceled)

8. A structure comprising:
a semiconductor substrate having opposite top and bottom surfaces;
an electrically conductive first through via extending through said substrate from said top surface to said bottom surface, said first through via electrically isolated from said substrate by a first dielectric layer:
an electrically conductive second through via extending through said substrate from said top surface to said bottom surface, said second through via electrically isolated from said substrate by a second dielectric layer;
an electrically conductive third through via in said first region of said substrate and extending through said substrate from said top surface to said bottom surface, said third through via electrically isolated from said substrate by a third dielectric layer;
an electrically conductive fourth through via in said first region of said substrate and extending through said substrate from said top surface to said bottom surface, said fourth through via electrically isolated from said substrate by a fourth dielectric layer;
a first region of said substrate intervening between said first and second through vias;
a second region of said substrate in said first region of said substrate intervening between said third and fourth through via;
an electrically conductive first contact formed on a top surface of said first through via, proximate to said top surface of said substrate, said first contact electrically isolated from said substrate by a fifth dielectric layer;
an electrically conductive second contact formed on a bottom surface of said first through via and on a bottom surface of said second through via proximate to said bottom surface of said substrate, said second contact electrically connecting said second and fourth through vias, said second contact electrically isolated from said substrate by a sixth dielectric layers;
an electrically conductive third contact formed on a top surface of said second through via proximate to said top surface of said substrate, said fourth contact electrically connecting said third and fourth through vias, said third contact electrically isolated from said substrate by a seventh dielectric layer;
an electrically conductive fourth contact formed on a top surface of said third through via and on a top surface of said fourth through via proximate to said top surface of said substrate, said fourth contact electrically connecting said third and fourth through vias, said fourth contact electrically isolated from said substrate by an eighth dielectric layer;
an electrically conductive fifth contact formed on a bottom surface of said first and third through vias proximate to said bottom surface of said substrate, said fifth contact electrically connecting said first and third through vias, said fifth contact electrically isolated from said substrate by a ninth dielectric layer; and
said first contact, said third contact, said fourth contact, said first through via and said fourth through via formed from a first material and said second contact, said fifth contact, said second through via and said third through via formed from a second material, said first material different from said second material.

9. The structure of claim 8, wherein said first and second materials are dependently selected from the group consisting of tungsten, aluminum, copper, titanium tantalum, titanium nitride, tantalum nitride, a first polysilicon and a second polysilicon, the first polysilicon and the second polysilicon having different dopant types, different doping levels or both different doping types and different dopant concentrations.

10. The structure of claim 8, further including integrated circuits formed in a third region of said substrate and electrically connected to said first and third contacts.

11. The structure of claim 8, wherein said substrate comprises silicon.

12-16. (canceled)
